(19) United States
(12) Patent Application Publication
(10) Pub. No.: US 2026/0251988 A1
(43) Pub. Date: Aug. 27, 2026

(54) POSITIONING APPARATUS, EXPOSURE APPARATUS, AIR SENSOR, AND ARTICLE MANUFACTURING METHOD

(71) Applicant: CANON KABUSHIKI KAISHA, Tokyo (JP)

(72) Inventors: NAOKI FUNABASHI, Tochigi (JP); YUSUKE ENDO, Tochigi (JP); MIZUKI NARIMATSU, Tochigi (JP); SHIGEO KOYA, Tochigi (JP); YUICHIRO MORIKUNI, Tochigi (JP); SHINZO UCHIYAMA, Tochigi (JP)

(21) Appl. No.: 19/546,694

(22) Filed: Feb. 23, 2026

(30) Foreign Application Priority Data
Feb. 26, 2025 (JP) 2025-029372

(51) Int. Cl. G03F 9/00; G01B 13/06

(52) U.S. Cl. CPC G03F 9/7057; G01B 13/065; G03F 9/7026

(57) ABSTRACT

A positioning apparatus that positions a substrate includes a substrate stage mechanism configured to drive the substrate, a measurement device configured to measure a height of the substrate, an air sensor configured to measure the height of the substrate based on a pressure in a pipe line while discharging air through the pipe line, and a controller configured to control the substrate stage mechanism. A measurement range as a range of heights that can be measured by the air sensor is narrower than a range of heights that can be measured by the measurement device. The controller controls the substrate stage mechanism based on an output from the measurement device to make the height at the measurement location on the substrate fall within the measurement range.

### BACKGROUND

### Field of the Technology

The present disclosure relates to a positioning apparatus, an exposure apparatus, an air sensor, and an article manufacturing method.

### Description of the Related Art

Japanese Patent Laid-Open No. 2010-109378 discloses a lithography projection apparatus including a first sensor as a process-independent sensor such as an air micrometer and a second sensor as a process-dependent sensor. The measurement value obtained by the second sensor has an offset error (PDOE) that can be dependent on a process. The lithography projection apparatus can execute lithography processing at a plurality of positions on a substrate by scanning the substrate immediately below the first and second sensors. By using the measurement values obtained by the first and second sensors, a map storing a PDOE of the second sensor at each position on the substrate at which measurement has been performed is prepared.

An air sensor is a sensor that measures the height or position of a measurement target based on a pressure in a pipeline while discharging air through the pipeline. As the distance (that is, the working distance) between the outlet of the pipeline and the measurement target increases, the measurement accuracy and sensitivity decrease, whereas as the working distance decreases, the measurement accuracy and sensitivity increase. Accordingly, in order to implement high measurement accuracy, it is necessary to reduce the working distance. However, reducing the working distance may cause the air sensor to collide with the measurement target.

### SUMMARY

The present disclosure provides a technique advantageous in preventing the collision between an air sensor and a substrate as a measurement target.

The present disclosure provides a positioning apparatus that positions a substrate, the apparatus comprising: a substrate stage mechanism configured to drive the substrate; a measurement device configured to measure a height of the substrate; an air sensor configured to measure the height of the substrate based on a pressure in a pipeline while discharging air through the pipeline; and a controller configured to control the substrate stage mechanism, wherein a measurement range as a range of heights that can be measured by the air sensor is narrower than a range of heights that can be measured by the measurement device, and the controller controls the substrate stage mechanism based on an output from the measurement device to make the height at the measurement location on the substrate fall within the measurement range.

Features of the present disclosure will become apparent from the following description of embodiments with reference to the attached drawings. The following description of embodiments is described by way of example.

### BRIEF DESCRIPTION OF THE DRAWINGS

The accompanying drawings, which are incorporated in and constitute a part of the specification, illustrate embodiments of the present disclosure, and together with the description, serve to explain the principles of the embodiments.

FIG. 1A is a view schematically showing the arrangement of an exposure apparatus according to one embodiment which incorporates a height measurement device according to one embodiment;

FIG. 1B is a view schematically showing the arrangement of the exposure apparatus according to one embodiment which incorporates the height measurement device according to the embodiment;

FIG. 1C is a view schematically showing the arrangement of the exposure apparatus according to one embodiment which incorporates the height measurement device according to the embodiment;

FIG. 2 is a view schematically showing a top view of a substrate stage;

FIG. 3A is a view schematically showing a first arrangement example of an air sensor;

FIG. 3B is a view schematically showing a second arrangement example of the air sensor;

FIG. 4A is a view for explaining a measuring method or positioning method according to a comparative example;

FIG. 4B is a view for explaining a measuring method or positioning method according to the embodiment; and

FIG. 5 is a view showing a sequence of driving a substrate so as to match a measurement location on a substrate with the central position (best focus position) of the detection range of a height air sensor.

### DESCRIPTION OF THE EMBODIMENTS

Hereinafter, embodiments will be described in detail with reference to the attached drawings. Note, the following embodiments are not intended to limit the scope of the claims. Multiple features are described in the embodiments, but it is not the case that all such features are required, and multiple such features may be combined as appropriate. Furthermore, in the attached drawings, the same reference numerals are given to the same or similar configurations, and redundant description thereof is omitted.

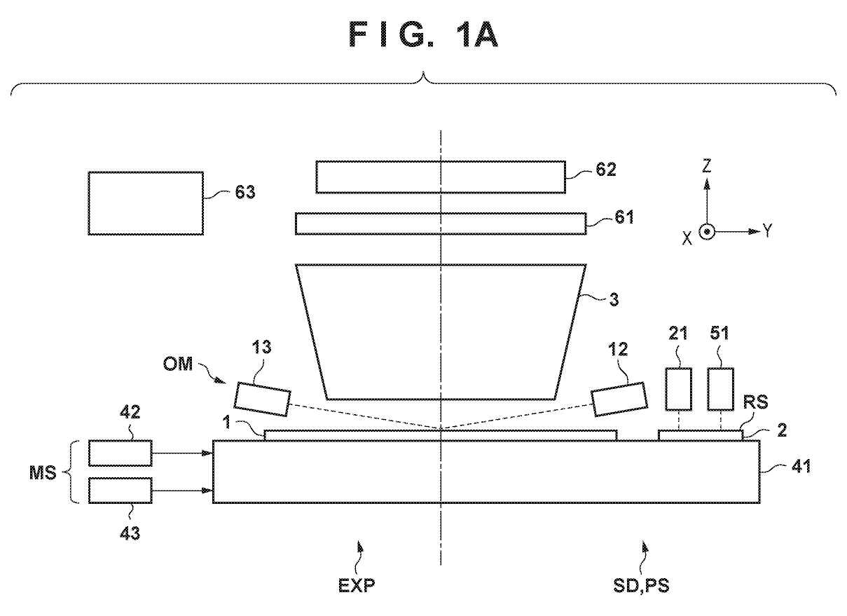

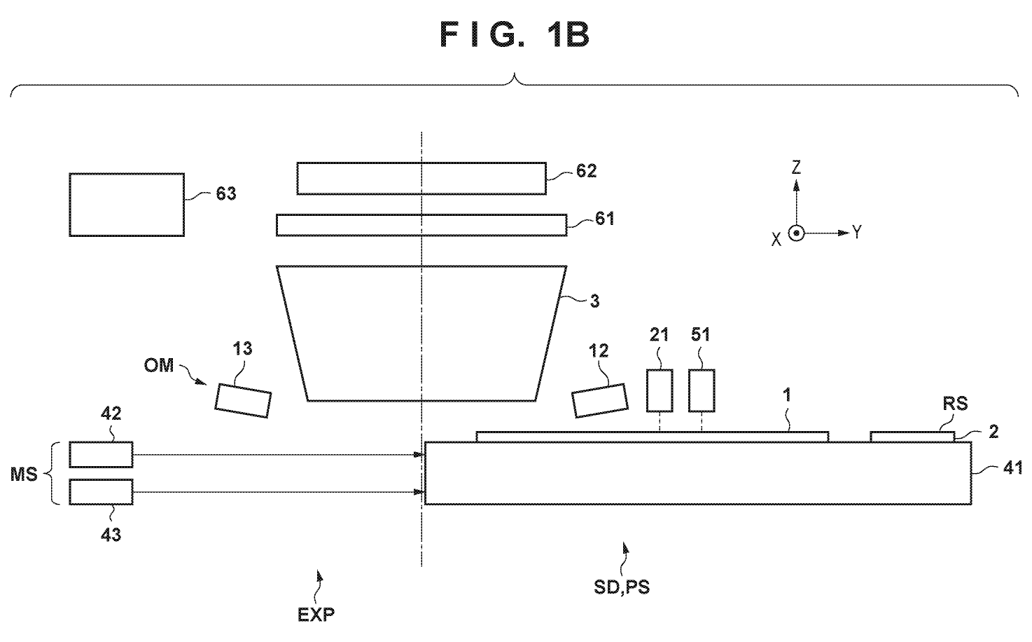

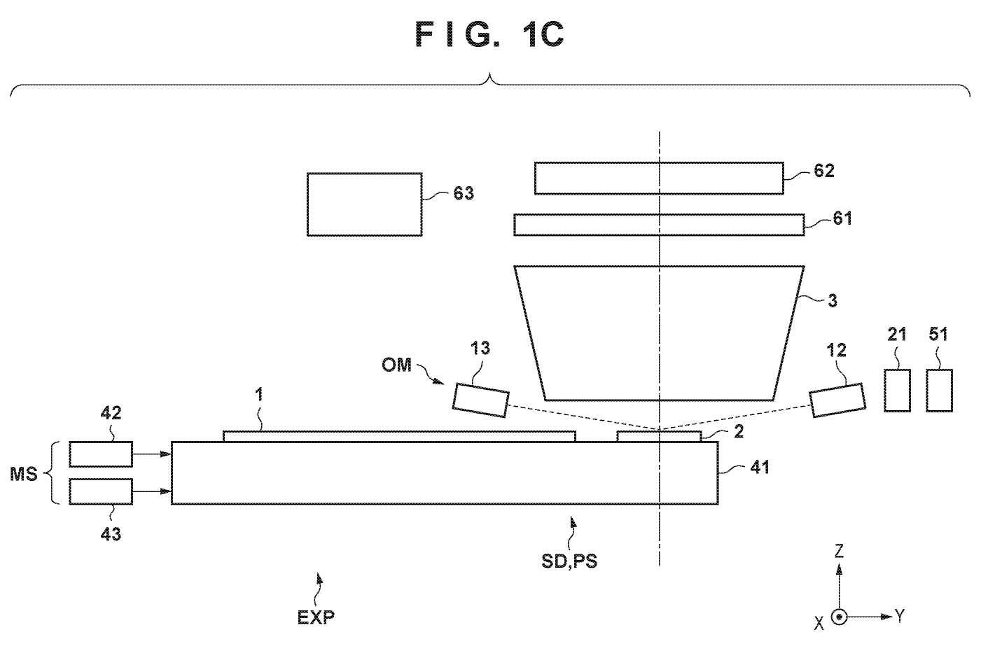

FIGS. 1A, 1B, and 1C schematically show the arrangement of an exposure apparatus EXP according to one embodiment which incorporates a positioning apparatus PS according to one embodiment. The exposure apparatus EXP can include an illumination optical system 62 that illuminates an original plate 61 and a projection optical system 3 that projects a pattern of an original plate 61 onto a substrate 1. The exposure apparatus EXP can be configured to perform exposure on the substrate 1 by causing the projection optical system 3 to project the pattern of the original plate 61 onto the substrate 1. The exposure apparatus EXP can include the positioning apparatus PS that positions the substrate 1, an illumination optical system 62 that illuminates the substrate 1, the projection optical system 3 that projects the pattern of the original plate 61 onto the substrate 1, an optical measurement device OM that measures the height of the substrate 1, and a controller 63.

The optical measurement device OM is an oblique incidence measurement device that irradiates a surface of the substrate 1 with light and receives reflected light from the substrate 1. More specifically, the optical measurement device OM can include a light projector 12 that projects patterned light onto the substrate 1 and a light receiver 13 that receives reflected light from the substrate 1. The optical measurement device OM can generate a measurement error dependent on the internal structure (the structure under the uppermost surface) of the substrate 1 because light is reflected by the internal structure of the substrate 1 in addition to the uppermost surface of the substrate 1. The controller 63 is implemented by, for example, a programmable logic device (PLD) such as a field programmable gate array (FPGA), an application specific integrated circuit (ASIC), a general-purpose or dedicated computer installed with a program, or a combination of all or some of them.

The exposure apparatus EXP or the positioning apparatus PS can include a substrate stage mechanism SD that holds and drives the substrate 1, a measurement device 51 that measures the height of the substrate 1, and an air sensor 21 that measures the height of the substrate 1. The controller 63 can function as a controller that controls the positioning apparatus PS. The exposure apparatus EXP or the positioning apparatus PS may include a measurement system MS that measures the position and posture of the substrate stage 41 and can control the position and posture of a substrate stage 41 based on an output from the measurement system MS. The measurement system MS can include, for example, a plurality of measurement devices including measurement devices 42 and 43. The stage measurement system MS can measure the substrate stage 41 concerning six axes by using the plurality of measurement devices. The positioning apparatus PS can control the substrate stage 41 concerning the six axes based an output from the stage measurement system MS. The plurality of measurement devices may include, for example, a plurality of interferometers or a plurality of encoders or may include one or a plurality of interferometers or one or a plurality of encoders.

The measurement device 51 is a measurement device that optically, electrostatically, or magnetically measures the height of the substrate 1. For example, the measurement device 51 can be a spectral interference laser displacement meter. Alternatively, the measurement device 51 can be an oblique incidence measurement device that irradiates the substrate 1 with light and receives reflected light from the substrate 1. The air sensor 21 can also be called an air microsensor. The air sensor 21 can be configured to be able to measure the height of the substrate 1 with a resolution of nanometer order or 1nm or higher. The air sensor 21 can be configured to measure the height of the substrate 1 based on the pressure of a pipeline while discharging air through the pipeline. The measurement result obtained by the air sensor 21 is unaffected by the internal structure of the substrate 1.

The exposure apparatus EXP can include a reference plate 2 having a reference surface RS. For example, the reference plate 2 can have a reference mark whose position is detected by an alignment sensor (not shown) and can be placed on the substrate stage 41. The reference surface RS can be a flat surface. The measurement range that is the range of heights that can be measured by the air sensor 21 is narrower than the range of heights that can be measured by the measurement device 51. The controller 63 can operate to make the height at the measurement location on the substrate 1 (its surface) fall within the measurement range of the air sensor 21 by controlling the substrate stage mechanism SD based on an output from the measurement device 51.

FIG. 1A schematically shows a state in which the height at a first measurement location on the substrate 1 is measured by the optical measurement device OM and a state in which the height of the reference surface RS is measured by using the measurement device 51 and/or the air sensor 21. FIG. 1B schematically shows a state in which the height at a measurement location on the substrate 1 is measured by using the measurement device 51 and/or the air sensor 21. FIG. 1C schematically shows a state in which the height of the reference surface RS is measured by the optical measurement device OM.

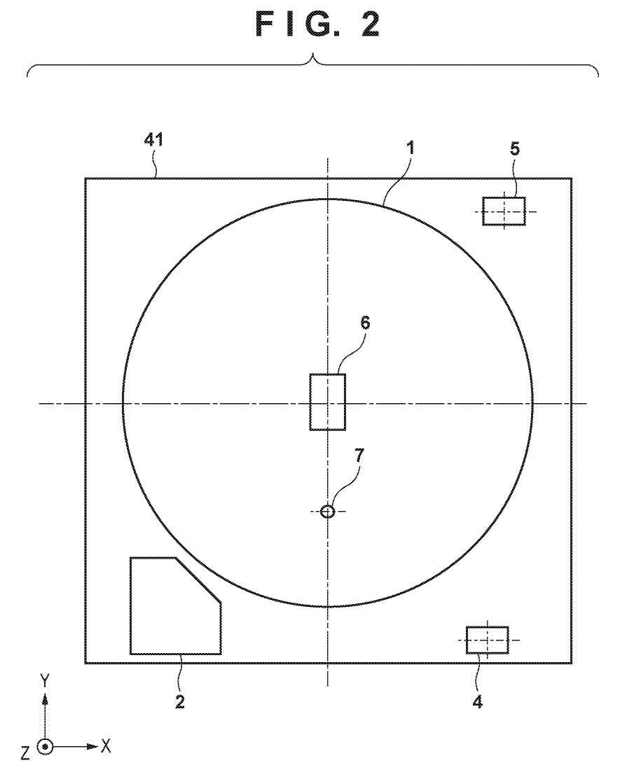

FIG. 2 schematically shows a top view of the substrate stage 41. Additional reference plates 4 and 5 may be arranged on the substrate stage 41. The reference plates 4 and 5 can have reference marks. The thermal deformation of the top plate of the substrate stage 41 can be evaluated by measuring the positions of the respective reference marks of the reference plates 2, 4, and 5 using an off-axis scope (not shown).

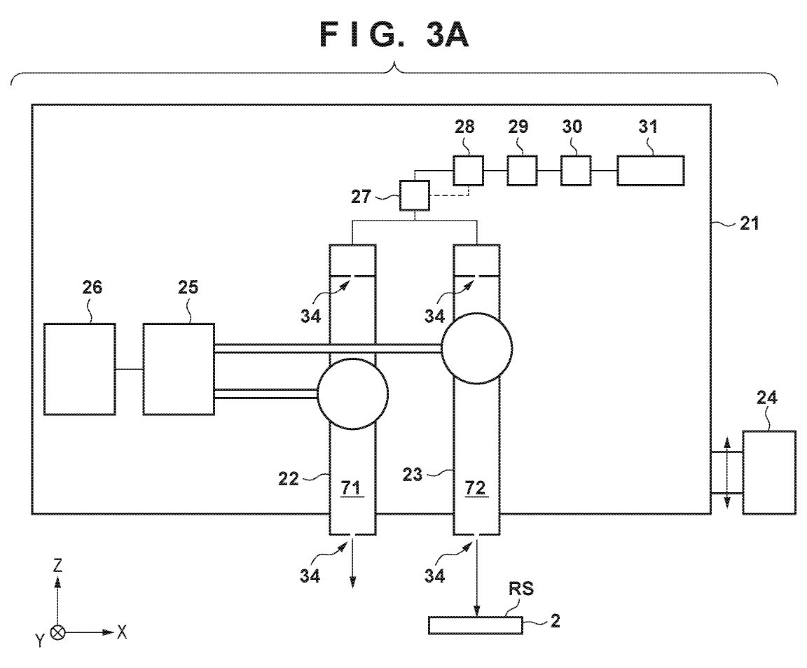

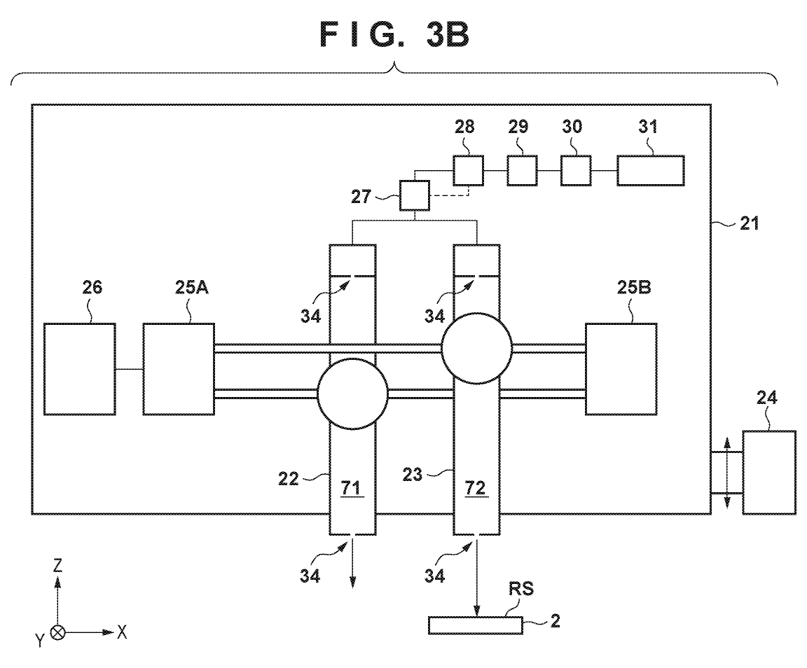

FIG. 3A schematically shows a first arrangement example of the air sensor 21. The air sensor 21 can include a reference nozzle 22 that discharges air through a first pipeline 71, a measurement nozzle 23 that discharges air through a second pipeline 72, and a differential pressure sensor 25 that detects the difference between the pressure in the first pipeline 71 and the pressure in the second pipeline 72. The air sensor 21 may further include a mass flow controller 28 and can supply air to the reference nozzle 22 and the measurement nozzle 23 through the mass flow controller 28. An air supply source 31 can supply air to the mass flow controller 28. A filter 29 and a valve 30 can be arranged between the mass flow controller 28 and the air supply source 31. The exposure apparatus EXP or the positioning apparatus PS can include a driving mechanism (for example, an elevating mechanism) 24 that moves the air sensor 21. The mass flow controller 28 can supply air to the reference nozzle 22 and the measurement nozzle 23 through a sensor 27 such as a pressure gauge or flowmeter. The air sensor 21 may further include a processor 26. The processor 26 can convert an output from the differential pressure sensor 25 into height information. The reference nozzle 22 and the measurement nozzle 23 each can be provided with orifices 34 at the inlet and the outlet.

The mass flow controller 28 supplies air whose pressure and flow rate are constantly regulated to the reference nozzle 22 and the measurement nozzle 23. The mass flow controller 28 can operate so as to maintain the pressure on the outlet side of the mass flow controller 28 at a predetermined pressure (for example, 70 kPa ± 0.01 kPa) based on the output from the sensor 27. The diameter of each orifice 34 may fall within, for example, the range of 0.1 mm to 0.2 mm. Since the orifice 34 operates as a resistance to the flow of air, the pressure in the first pipeline 71 of the reference nozzle 22 can be maintained constant. The pressure in the second pipeline 72 of the measurement nozzle 23 becomes a value corresponding to the distance between the measurement nozzle 23 and a measurement target surface, and the pressure in the first pipeline 71 of the reference nozzle 22 and the pressure in the second pipeline 72 of the measurement nozzle 23 are supplied to the differential pressure sensor 25. Accordingly, a differential pressure corresponding to the distance between the measurement nozzle 23 and the measurement target surface is supplied to the differential pressure sensor 25. The air sensor 21 is free from any measurement error due to an internal structure existing below a measurement target surface.

The output voltage of the differential pressure sensor 25 can depend on the diameter of the orifice 34. As the diameter of the orifice 34 increases, the measurement resolution increases. On the other hand, the working distance increases, and the time required to measure shortens. In contrast to this, as the diameter of the orifice 34 decreases, the measurement resolution decreases. On the other hand, the working distance decreases, and the time required to measure increases. When, for example, the height of the reference surface RS changes by 1 nm, the diameter of the orifice 34 can be determined so as to change the output voltage of the differential pressure sensor 25 by 2 mV. In this case, the working distance is, for example, 35 micrometers.

The controller 63 can calibrate the air sensor 21 based on an output from the air sensor 21 when the positioning apparatus PS changes the height of the substrate stage 41 by a predetermined height. The calibration of the air sensor 21 can include causing the processor 26 to update the conversion formula for converting the output voltage of the differential pressure sensor 25 into a height. The controller 63 may calibrate the air sensor 21 based on a change in output from the differential pressure sensor 25 when causing the positioning apparatus PS to change the height of the substrate stage 41 by increments (for example, an increase or decrease by increments of 1 nm). In general, the conversion formula is nonlinear. The conversion formula may include a time drift component and/or a temperature-dependent component. The base of a reference plate is formed of a metal or ceramic material having a small thermal expansion coefficient, and a reference mark can be formed of silica glass.

The controller 63 can calibrate the air sensor 21 such that the result obtained by measuring the height of the reference surface RS of the reference plate 2 using the air sensor 21 becomes 0. Alternatively, the controller 63 may obtain a corrected measurement value by holding, as a reference value, the result obtained by measuring the height of the reference surface RS of the reference plate 2 using the air sensor 21 and subtracting the reference value from the measurement value obtained by measuring a height at a measurement location using the air sensor 21. In this case, the calibration includes the operation of holding the reference value. Likewise, the controller 63 can calibrate the optical measurement device OM such that the result obtained by measuring the height of the reference surface RS of the reference plate 2 using the optical measurement device OM becomes 0. Alternatively, the controller 63 may obtain a corrected measurement value by holding, as a reference value, the result obtained by measuring the height of the reference surface RS of the reference plate 2 using the optical measurement device OM and subtracting the reference value from the measurement value obtained by measuring a height at a measurement location using the optical measurement device OM. In this case, the calibration includes the operation of holding the reference value. Since the drift of the air sensor 21 is considerably large, the air sensor 21 can be calibrated as frequently as, for example, every nine seconds.

For example, the air sensor 21 and the optical measurement device OM each can be calibrated by using the reference surface RS of the reference plate 2. In a case where the difference between the results obtained by measuring a height at a measurement location on the substrate 1 using the air sensor 21 and the optical measurement device OM is equal to or more than a predetermined value (for example, 10 nm), the controller 63 can update or generate correction information. The controller 63 can update or generate correction information so as to match the measurement result obtained by the optical measurement device OM with the measurement result obtained by the air sensor 21.

The controller 63 can obtain a first result by measuring the height at the first measurement location on the substrate 1 and the height of the reference surface RS of the reference plate 2 using the optical measurement device OM. The controller 63 can also obtain a second result by measuring the height at the first measurement location on the substrate 1 and the height of the reference surface RS of the reference plate 2 using the air sensor 21. The controller 63 can also correct the result obtained by measuring the second measurement location on the substrate 1 using the optical measurement device OM based on the first result and the second result. The controller 63 can generate correction information for correcting the result obtained by measuring the second measurement location on the substrate 1 using the optical measurement device OM based on, for example, the first result and the second result. The controller 63 can generate correction information based on, for example, the difference between the first result and the second result. The controller 63 can obtain the height information of the second measurement location in a short time with high accuracy by correcting the result obtained by measuring the height at the second measurement location on the substrate 1 using the optical measurement device OM based on the correction information.

FIG. 3B schematically shows the second arrangement example of the air sensor 21. In the second arrangement example, a first differential pressure sensor 25A and a second differential pressure sensor 25B are arranged instead of the differential pressure sensor 25 in the first arrangement example. The first differential pressure sensor 25A detects the difference between the pressure in the first pipeline 71 and the pressure in the second pipeline 72. Likewise, the second differential pressure sensor 25B detects the difference between the pressure in the first pipeline 71 and the pressure in the second pipeline 72. The first differential pressure sensor 25A and the second differential pressure sensor 25B differ in sensitivity (and measurement range). The processor 26 can convert an output from the first differential pressure sensor 25A into height information. The processor 26 can also convert an output from the second differential pressure sensor 25B into height information.

The principle of a spectral interference laser displacement meter (to be referred to as a displacement meter hereinafter) that can be used as the measurement device 51. The displacement meter irradiates a reference surface and a measurement surface with, for example, the light output from a light source (for example, a laser). The reference surface is located in the displacement meter. The light applied to the reference surface is reflected by the reference surface to form reference light. The light applied to the measurement surface is reflected by the measurement surface to form measurement light. Reference light and measurement light interfere with each other to form interference light. The intensity of interference light with each wavelength changes in accordance with the difference between the optical path length of reference light and the optical path length on a measurement surface. For example, a diffraction grating or the like is used to disperse interference light to make it possible to measure the intensity of light of each wavelength. This can measure the optical path length difference and eventually can measure the relative position of the measurement surface relative to the reference surface. The measurement time required for measurement by the displacement meter is short, for example, 0.1 msec.

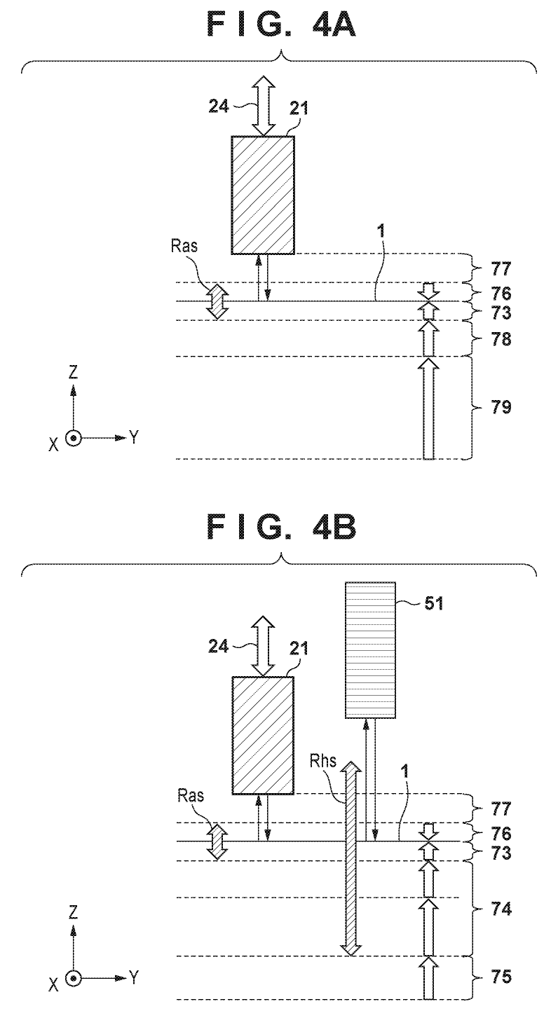

FIG. 4A is a view for explaining a measuring method and a positioning method according to a comparative example. FIG. 4B is a view for explaining the measuring method and the positioning method according to the present embodiment. Referring to FIGS. 4A and 4B, reference symbol Ras denotes a range (measurement range) in which the air sensor 21 can perform measurement, and reference symbol Rh2 denotes a range (measurement range) in which the measurement device 51 can perform measurement. Reference numeral 73 denotes a range of the detection range Ras of the air sensor 21 which is located below the center of the detection range Ras. Reference numeral 76 denotes a range of the detection range Ras of the air sensor 21 which is located above the center of the detection range Ras. Reference numeral 78 denotes a range located below the lower end of the detection range Ras and near the detection range Ras. Reference numeral 79 denotes a range below the lower end of the range 78. Reference numeral 77 denotes an interval in which an output from the air sensor 21 is saturated. Reference numeral 74 denotes a range that coincides with the detection range Rhs of the measurement device 51 but does not coincide with the detection range Ras of the air sensor 21. Reference numeral 75 denotes a range that coincides with neither the detection range Rhs of the measurement device 51 nor the detection range Ras of the air sensor 21.

The operation of a comparative example will be described below with reference to FIG. 4A. In the comparative example, the height of the substrate 1 is controlled by using only the air sensor 21. Assume that in this case, the time required for one measurement by the air sensor 21 is 300 msec, the working distance of the air sensor 21 is 30 μm, and the measurement range Ras is ±1 μm. Note that μm means micrometer.

Assuming that the substrate 1 is located in the range 79 in the initial state, the substrate stage mechanism SD drives the surface of the substrate 1 to a height near the measurement range Ras of the air sensor 21. Since the working distance of the air sensor 21 is 30 μm, caution is required to drive the surface of the substrate 1 to a height near the measurement range Ras. When the surface of the substrate 1 is moved to a height near the measurement range Ras (for example, the range 78) of the air sensor 21, the substrate 1 can collide with the air sensor 21 unless the substrate 1 is step-driven 30 μm or less at a time. Since the measurement range Ras is only ±1 μm, the substrate 1 may pass through the measurement range Ras in step driving. In this case, since an output from the air sensor 21 is saturated, it is possible to detect the entrance of the substrate 1 into the range 77 based on such saturation. If, for example, an output from the differential pressure sensor of the air sensor 21 is -5 V to +5 V, the air sensor 21 outputs +5 V at the time of saturation.

Subsequently, in the second step, since the measurement range Ras of the air sensor 21 is ±1 μm, the substrate 1 is gradually lowered to move the surface of the substrate 1 to the center of the measurement range Ras of the air sensor 21. Assuming that the range 79 is 20 μm x 10 steps = 200 μm, a total of 3,000 msec is required for measurement by the air sensor 21 in the first step. Assuming that step driving is performed with 2 μm x 10 steps = 20 μm, a total of 3,000 msec is required for measurement by the air sensor 21 in the second step.

In the third step, the positioning apparatus PS is controlled to make the surface of the substrate 1 fall within ±0.1 μm (best focus position) of the central position of the measurement range Ras based on the measurement result obtained in the second step. The position of the surface in the Z-axis direction at this time is measured by the measurement system MS and recorded. A total of 6,000 msec is required to position the surface of the substrate 1 at the best focus position (height). It can be said that it takes much time.

In this case, it is difficult to omit the second and subsequent measurements by the air sensor 21. Although there is available a method of driving the substrate 1 based on measurement by the measurement system MS, the driving accuracy achieved by the driving mechanism 24 that drives the air sensor 21 can be, for example, about ±1 μm. In addition, in consideration of an inclination of ±30 μm of the substrate 1 and a thickness error of ±20 μm (SEMI standards) of the substrate 1, the first step may be started from the range 78. Assuming that the range 78 is located at a position 50 μm away from the central position of the measurement range Ras of the air sensor 21, 900 msec is required for measurement, with the first step being 20 μm x 3 steps = 60 μm. In addition, since the second and subsequent steps cannot be omitted, 3,000 msec is required, with 2 μm x 10 steps = 20 μm. Accordingly, a total of about 3,900 msec is required in each of the second and subsequent measurements.

The operation of the embodiment will be described below with reference to FIG. 4B. Assume that in this case, a spectral interference laser displacement meter (to be referred to as a displacement meter hereinafter) is used as the measurement device 51. Assume also that the time required for one measurement by the measurement device 51 (displacement meter) is 0.1 msec, the working distance of the measurement device 51 is 11.8 mm, and the measurement range Rhs is ±500 μm.

With regard to the positional relationship between the air sensor 21 and the measurement device 51, for example, it can be guaranteed in advance that they are located within ±200 μm of each other. This accuracy can be reliably guaranteed by machining accuracy and assembly adjustment. In the first measurement, 6,000 msec is required to execute the first step to the third step. Note however that the measurement value obtained by the measurement device 51 is stored while the surface of the substrate 1 is positioned at the central position of the measurement range Ras of the air sensor 21.

In the second and subsequent measurements, the measurement device 51 may measure the height of the substrate 1, and the position of the substrate 1 may be adjusted based on the measurement result. This makes it possible to greatly reduce the time required until the air sensor 21 performs measurement.

In the second step in the present embodiment, it is possible to start an operation from the range 74 based on an output from the measurement device 51. Immediately after one measurement (0.1 msec) is performed upon starting of an operation from the range 74, the surface of the substrate 1 can be moved to the center of the detection range Ras of the air sensor 21. The air sensor 21 then performs one measurement (300 msec), and it is then checked whether the surface of the substrate 1 has entered the detection range Ras. Finally, the positioning apparatus PS is controlled so as to make the surface of the substrate 1 fall within ±0.1 μm (best focus) of the central position of the measurement range Ras based on the measurement result obtained by the air sensor 21.

The time required for each of the second and subsequent measurements which was 3,900 msec in the comparative example is reduced to about 300 msec in the present embodiment.

In this case, a spectral interference laser displacement meter is presented as an example of the measurement device 51. However, for example, a capacitance sensor, a laser displacement meter, a laser interferometer, or an encoder may be used. In addition, the measurement device 51 may be placed on the substrate stage or the positional relationship between the measurement device 51 and the air sensor 21 and the position of the substrate 1 may be measured from a position independent of the air sensor 21 and the substrate stage 41.

After the height of the substrate 1 is adjusted by using the air sensor 21, that is, after the substrate 1 is positioned in the Z-axis direction, the driving mechanism 24 retracts the air sensor 21 to the retraction position. Thereafter, an exposure operation is performed on the substrate 1. When the air sensor 21 measures the next substrate 1, the driving mechanism 24 drives the air sensor 21 to the measurement position.

Although in the above embodiment, the measurement device 51 is fixed, the measurement device 51 may be driven (moved up and down) together with the air sensor 21 by the driving mechanism 24.

For example, the air sensor 21 may be retracted based on detection, such as detecting that the substrate 1 has suddenly tilted or the holding function of a substrate chuck mounted on the substrate stage 41 with respect to the substrate 1 is lost. This can prevent the collision between the substrate 1 and the air sensor 21.

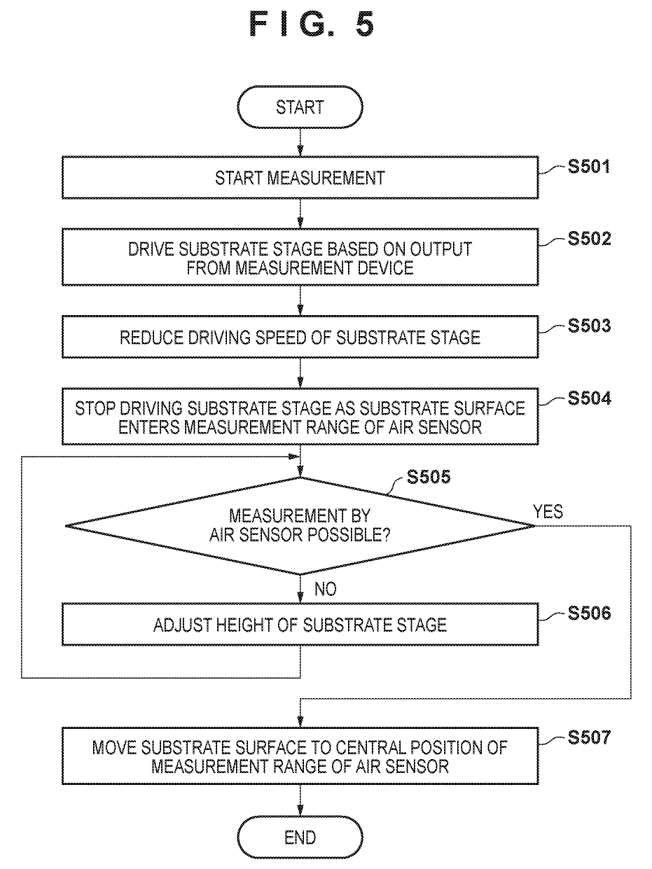

FIG. 5 exemplarily shows a procedure for driving the substrate 1 (the substrate stage 41) so as to match a measurement location on the substrate 1 (its surface) with the central position (best focus position) of the detection range Ras of the air sensor 21. The controller 63 controls this procedure. In step S501, the controller 63 causes the measurement device 51 to start measuring the height at the measurement location on the substrate 1. In step S502, the controller 63 controls the substrate stage mechanism SD based on an output from the measurement device 51. More specifically, the controller 63 controls the substrate stage mechanism SD to move the substrate 1 (the substrate stage 41) upward so as to bring the height at the measurement location on the substrate 1 close to the central position of the detection range Ras.

In step S503, the controller 63 reduces the driving speed of the substrate stage mechanism SD with respect to the substrate as the height at the measurement location on the substrate 1 approaches the measurement range Ras based on an output from the measurement device 51. In step S504, the controller 63 causes the substrate stage mechanism SD to stop driving the substrate 1 as the height at the measurement location on the substrate 1 enters the measurement range Ras.

In step S505, the controller 63 causes the air sensor 21 to measure the height at the measurement location on the substrate 1 while causing the substrate stage mechanism SD to stop driving the substrate 1. If an output from the air sensor 21 falls within a predetermined range, that is, if the air sensor 21 can measure the measurement location on the substrate 1, the controller 63 executes step S507. In contrast to this, if an output from the air sensor 21 does not fall within a predetermined range, that is, if the air sensor 21 cannot measure the measurement location on the substrate 1, the controller 63 executes step S506.

In step S507, the controller 63 controls the substrate stage mechanism SD to set the height at the measurement location on the substrate 1 at a target height, that is, the central position of the measurement range Ras, based on the output from the air sensor 21 in step S505. In this case, the controller 63 controls the substrate stage mechanism SD to set the height at the measurement location on the substrate 1 at the target height based on an output from the air sensor 21 which is obtained by checking whether the output falls within the predetermined range.

In step S506, if the output from the air sensor 21 does not fall within the predetermined range, the controller 63 controls the substrate stage mechanism SD to make the height at the measurement location on the substrate 1 fall within the predetermined range by using the air sensor 21.

A manufacturing method of manufacturing articles (semiconductor IC elements, liquid crystal display elements, MEMS, and the like) by using the above exposure apparatus will be described next. An article is manufactured using the above exposure apparatus by processing a substrate (a wafer, a glass substrate, or the like) coated with a photosensitive agent in an exposure step of exposing the substrate, a developing step of developing the substrate (photosensitive agent), and other known processing steps of processing the developed substrate. Other known steps include, for example, etching, resist stripping, dicing, bonding, and packaging. This article manufacturing method can manufacture articles with higher quality than conventional articles.

While the present disclosure has been described with reference to exemplary embodiments, it is to be understood that the present disclosure is not limited to the disclosed exemplary embodiments. The scope of the following claims is to be accorded the broadest interpretation so as to encompass all such modifications and equivalent structures and functions.

This application claims the benefit of Japanese Patent Application No. 2025-029372, filed February 26, 2025, which is hereby incorporated by reference herein in its entirety.

What is claimed is:

1. A positioning apparatus that positions a substrate, the apparatus comprising:
a substrate stage mechanism configured to drive the substrate;
a measurement device configured to measure a height of the substrate;
an air sensor configured to measure the height of the substrate based on a pressure in a pipeline while discharging air through the pipeline; and
a controller configured to control the substrate stage mechanism,
wherein a measurement range as a range of heights that can be measured by the air sensor is narrower than a range of heights that can be measured by the measurement device, and
the controller controls the substrate stage mechanism based on an output from the measurement device to make the height at the measurement location on the substrate fall within the measurement range.

2. The apparatus according to claim 1, wherein the controller reduces a driving speed of the substrate stage mechanism with respect to the substrate as the height at the measurement location on the substrate approaches the measurement range based on an output from the measurement device.

3. The apparatus according to claim 2, wherein the controller causes the substrate stage mechanism to stop driving the substrate as the height at the measurement location on the substrate falls within the measurement range.

4. The apparatus according to claim 3, wherein the controller measures the height of the substrate by using the air sensor while causing the substrate stage mechanism to stop driving the substrate.

5. The apparatus according to claim 4, wherein the controller controls the substrate stage mechanism to set the height at the measurement location on the substrate at a target height based on an output from the air sensor when the output from the air sensor falls within a predetermined range.

6. The apparatus according to claim 5, wherein the controller controls the substrate stage mechanism to set the height at the measurement location on the substrate at a target height based on an output from the air sensor which is obtained for checking whether the output of the air sensor falls within the predetermined range.

7. The apparatus according to claim 5, wherein the controller controls the substrate stage mechanism to make the height at the measurement location on the substrate fall within the predetermined range by using the air sensor when the output from the air sensor does not fall within the predetermined range.

8. The apparatus according to claim 1, wherein the measurement device optically, electrostatically, or magnetically measures the height of the substrate.

9. The apparatus according to claim 1, wherein the measurement device is an oblique incidence measurement device configured to irradiate the substrate with light and receive reflected light from the substrate.

10. The apparatus according to claim 1, wherein the substrate stage mechanism includes a substrate stage configured to hold the substrate, a driving mechanism configured to drive the substrate stage, and a measurement system configured to measure a position and a posture of the substrate stage, and
the controller controls the position and the posture of the substrate stage based on an output from the measurement system.

11. The apparatus according to claim 10, wherein the controller calibrates the air sensor based on an output from the air sensor when changing the height of the substrate stage by a predetermined height based on an output from the measurement system.

12. The apparatus according to claim 1, wherein the air sensor comprises a reference nozzle configured to discharge air through a first pipeline, a measurement nozzle configured to discharge air through a second pipeline, and a differential pressure sensor configured to detect a difference between a pressure in the first pipeline and a pressure in the second pipeline.

13. The apparatus according to claim 12, wherein the air sensor further includes a mass flow controller and supplies air to the reference nozzle and the measurement nozzle through the mass flow controller.

14. The apparatus according to claim 1, wherein the air sensor includes
a reference nozzle configured to discharge air through a first pipeline,
a measurement nozzle configured to discharge air through a second pipeline,
a first differential pressure sensor configured to detect a difference between a pressure in the first pipeline and a pressure in the second pipeline, and
a second differential pressure sensor configured to detect a difference between a pressure in the first pipeline and a pressure in the second pipeline, and
the first differential pressure sensor and the second differential pressure sensor differ in sensitivity.

15. An exposure apparatus that causes a projection optical system to project a pattern of an original plate onto a substrate and exposes the substrate to light, the apparatus comprising a positioning apparatus configured to position the substrate,
wherein the positioning apparatus comprises:
a substrate stage mechanism configured to drive the substrate;
a measurement device configured to measure a height of the substrate;
an air sensor configured to measure the height of the substrate based on a pressure in a pipeline while discharging air through the pipeline; and
a controller configured to control the substrate stage mechanism,
wherein a measurement range as a range of heights that can be measured by the air sensor is narrower than a range of heights that can be measured by the measurement device, and
the controller controls the substrate stage mechanism based on an output from the measurement device to make the height at the measurement location on the substrate fall within the measurement range.

16. An article manufacturing method comprising:
exposing a substrate to light by an exposure apparatus defined in claim 15;
developing the substrate having undergone the exposing; and
obtaining an article by processing the substrate having undergone the developing.

17. An air sensor comprising:
a reference nozzle configured to discharge air through a first pipeline;
a measurement nozzle configured to discharge air through a second pipeline;
a first differential pressure sensor configured to detect a difference between a pressure in the first pipeline and a pressure in the second pipeline; and
a second differential pressure sensor configured to detect a difference between a pressure in the first pipeline and a pressure in the second pipeline,
wherein the first differential pressure sensor and the second differential pressure sensor differ in sensitivity.

18. A positioning apparatus comprising:
an air sensor defined in claim 17 which is configured to measure a height of a substrate;
a substrate stage mechanism configured to adjust the height of the substrate; and
a controller configured to control the substrate stage mechanism based on an output from the air sensor.

19. An exposure apparatus that projects a pattern of an original plate onto a substrate using a projection optical system and exposes the substrate to light, the apparatus comprising a positioning apparatus configured to position the substrate,
wherein the positioning apparatus is a positioning apparatus defined in claim 18.

20. An article manufacturing method comprising:
exposing a substrate to light by using an exposure apparatus defined in claim 19;
developing the substrate having undergone the exposing; and
obtaining an article by processing the substrate having undergone the developing.
